(19) United States
(12) Patent Application Publication
(10) Pub. No.: US 2025/0318096 A1
(43) Pub. Date: Oct. 9, 2025

(54) Method for Automatic Reloading of SMD Component Reels on SMD Assembly Machines

(71) Applicant: KUKA Deutschland GmbH, Augsburg (DE)

(72) Inventors: Adil Akbas, Augsburg (DE); Erich Block, Augsburg (DE); Pascal Caprano, Augsburg (DE); Friedrich Sterz, Augsburg (DE)

(73) Assignee: KUKA Deutschland GmbH, Augsburg (DE)

(21) Appl. No.: 18/860,891

(22) PCT Filed: Apr. 26, 2023
(86) PCT No.: PCT/EP2023/060969

§ 371 Date: Oct. 28, 2024

(30) Foreign Application Priority Data
May 2, 2022 (DE) 10 2022 110 770.1

(51) Int. Cl. H05K 13/02

(52) U.S. Cl. CPC H05K 13/021; H05K 13/0215

(57) ABSTRACT

A method for automatically reloading SMD component reels on SMD assembly machines wherein SMD component reels between an exchange magazine of an SMD assembly machine and a belt connector are automatically handled by a robot arm controlled by a robot controller in a force/torque-controlled movement control mode of the robot arm.

### CROSS-REFERENCE TO RELATED APPLICATIONS

This application is a national phase application under 35 U.S.C. § 371 of International Patent Application No. PCT/EP2023/060969, filed Apr. 26, 2023 (pending), which claims the benefit of priority to German Patent Application No. DE 10 2022 110 770.1, filed May 2, 2022, the disclosures of which are incorporated by reference herein in their entirety.

### TECHNICAL FIELD

The invention relates to a method for automatically reloading SMD component reels on SMD assembly machines.

### BACKGROUND

CN 212711952 U relates to the technical field of SMT material pick-up devices, in particular to an SMT material pick-up machine that comprises a suction apparatus for applying suction to a material pick-up tape, a pressure roller and a driving apparatus, wherein the driving apparatus is connected to the suction apparatus and the pressure roller and the driving apparatus drives the suction apparatus to apply suction to the material pick-up tape and to convey the material pick-up tape to the position above the SMT material tape to fastened to the SMT material tape. The driving apparatus drives the pressure roller to roll over the surfaces of the material pick-up tape and the SMT material tape which are fastened to each other so that the material pick-up tape and the SMT material tape completely adhere to each other, and the success rate of covering the cover tape is improved. With such an apparatus, two SMD tapes from two SMD component reels can be automatically connected.

### SUMMARY

The object of the invention is to create a method by which SMD component reels can be changed fully automatically on SMD assembly machines, i.e. in particular without intermediate work steps to be carried out by a human.

The object is achieved by an exemplary method for automatically reloading SMD component reels on SMD assembly machines, comprising the steps:
automatic removal of a first SMD component reel which carries a first SMD tape that continues to run into the SMD assembly machine in ongoing operation of an SMD assembly machine, while the first SMD component reel is removed from an exchange magazine of the SMD assembly machine by means of a robot arm controlled by a robot controller in a force/torque-controlled movement control mode of the robot arm,
automatic threading of an end section of the first SMD tape into an automatic belt connector by means of the robot arm controlled by the robot controller and automatic separation of the first SMD component reel from the first SMD tape,
depositing the first SMD component reel into an intermediate storage magazine,
picking up a second SMD component reel that carries a second SMD tape from a pick-up magazine by means of the robot arm controlled by the robot controller,
automatic threading of a start section of the second SMD tape into the automatic belt connector by means of the robot arm controlled by the robot controller, and
automatic insertion of the second SMD component reel into the exchange magazine of the SMD assembly machine after a start section of the second SMD tape of the second SMD component reel has been automatically connected to the end section of the first SMD tape in the belt connector, while the second SMD tape runs off the second SMD component reel in the ongoing operation of the SMD assembly machine, wherein the second SMD component reel is inserted into the exchange magazine of the SMD assembly machine by means of the robot arm controlled by the robot controller in a force/torque-controlled movement control mode of the robot arm.

SMD assembly machines are machines for automatically populating electronic circuit boards with electronic components. The components are generally automatically placed on or glued to the circuit board and then automatically connected to the electrical conductor tracks of the circuit board, for example in a soldering bath, in order to create the electrical contacts. An example of an SMD assembly machine comprises a magazine station with unpopulated circuit boards, a conveyor system for feeding the circuit boards in a serial sequence, the actual assembly machine, in which the required SMD components are grasped one after the other and placed on the given circuit board at the designated locations, and an oven in which the SMD components placed on the circuit board are soldered. Finally, the finished, i.e. populated, circuit boards can be stacked in a delivery magazine. This manufacturing process is largely automated. The plurality of a single type of SMD components to be assembled are in each case provided on an SMD component reel as SMD tapes. Each individual SMD component requires its own SMD component reel. Each SMD component reel contains an SMD tape which comprises a carrier tape on which a plurality of SMD components of an identical design are attached at regular intervals. By means of the SMD component reel or by means of the SMD tape, each SMD component type can be continuously fed to the SMD assembly machine so that the SMD assembly machine can populate the circuit boards with the required SMD components continuously and preferably without interruption. However, when an SMD component reel is almost used up, i.e. almost all of the SMD components originally present on the SMD tape have been removed from the carrier tape and processed by the SMD assembly machine, the used SMD component reel must be removed and replaced by a fully populated new SMD component reel. In order for the SMD assembly machine to be able to continue producing uninterruptedly, the SMD tape of the new SMD component reel must be seamlessly attached to the end of the previous SMD tape of the SMD component reel that is running out. The joining should be carried out in such a way that, on the joined carrier tape, the distance of the first SMD component of the new SMD component reel from the last SMD component of the running-out SMD component reel corresponds as closely as possible to the standardized spacing of the plurality of SMD components from each other on an SMD component reel. Until now, this attachment of the beginning of the new SMD component reel to the SMD component reel that is running out is done manually and is generally not automated. This results in relatively high personnel costs, and a consistent quality is not guaranteed. There are already approaches to automating the joining process for connecting the beginning of the new SMD component reel to the end of the SMD component reel that is running out, but with these machines the end of the SMD component reel that is running out and the beginning of the new SMD component reel still have to be inserted manually.

The invention therefore also specifically addresses the fully automated reloading of new SMD component reels as successor reels for SMD component reels that are running out, wherein even an automatically operating belt connector is automatically loaded with the end of the SMD component reel that is running out and with the beginning of the new SMD component reel by the robot proposed according to the invention so that the end and beginning can be automatically connected in the automatically operating belt connector.

The SMD component reel comprises a tape drum and an SMD tape wound thereon. The SMD tape comprises a carrier tape, in particular with edge perforations at equal distances for precise positioning of the carrier tape, and a plurality of SMD components which have been mounted on the carrier tape at equal intervals from one another in a serial chain. The SMD component reel can be housed in a cassette described in more detail below. The SMD component reels described below can therefore always also be SMD component reels which comprise a cassette in which the tape drum is stored together with the SMD tape wound thereon.

According to the exemplary method, a first SMD component reel is first automatically removed which carries a first SMD tape which continues to run into the SMD assembly machine in ongoing operation of an SMD assembly machine. The first SMD component reel is initially located in an exchange magazine of the SMD assembly machine. The SMD assembly machine operates continuously automatically, even during the implementation of the method according to the invention, i.e. without interruption, so that during the automatic removal of the first SMD component reel from the exchange magazine, the first SMD tape continues to be drawn into the SMD assembly machine, in order to remove the SMD components located on the first SMD tape one after the other within the SMD assembly machine and to automatically populate circuit boards therewith. When automatically removing the first SMD component reel, it must be ensured during the movements of the robot arm, which automatically handles the first SMD component reel using a gripper guided by the robot arm, that no unacceptably high tensile forces are applied to the first SMD tape running off the first SMD component reel. The SMD assembly machine has a feeder that automatically feeds the first SMD tape into the SMD assembly machine. This specifies a maximum tensile force that can act on the first SMD tape. On the other hand, a minimum tensile force should also be maintained so that it is ensured that the first SMD tape is under a certain tensile stress so that the risk of loop formation or of a rising, sudden runout of the first SMD tape from the first SMD component reel is prevented. The robot controller can therefore be designed and configured to move the robot arm in such a way that during the automatic transport of the first SMD component reel from the exchange magazine to the belt connector, the first SMD tape continuing to run out of the first SMD component reel is under the permissible, i.e. desired, tensile stress. This can be achieved in particular in that the robot arm is controlled by the robot controller in a force/torque-controlled mode of operation so that the momentary tensile forces can be automatically detected at any time during the automatic transport of the first SMD component reel from the exchange magazine to the belt connector. The movement path that the robot arm specifies for the first SMD component reel can therefore be adapted thereto.

Typically, an exchange magazine has several slots, in each of which an SMD component reel of a specific SMD component type has been inserted. The slots are designed like slots so that a plurality of SMD component reels are arranged next to each other, with their main extension planes parallel to each other and with their reel axes of rotation parallel to each other. Preferably, the robot controller can therefore be designed and configured to control the robot arm in such a way that the robot arm, by means of its gripper which is moved by the robot arm, handles the gripped SMD component reel in such a way that the SMD component reel is pulled out of the exchange magazine in a direction parallel to its main extension plane, i.e. is pulled out in a direction running perpendicular to the reel rotation axis.

While the first SMD component reel is being removed from an exchange magazine of the SMD assembly machine by means of a robot arm controlled by a robot controller in a force/torque-controlled movement control mode of the robot arm, it can be provided in particular that the removed SMD component reel is only rotated about its reel rotation axis (Z-axis) during its movement and does not perform any other rotational movement, for example about the corresponding X-axis or Y-axis. A twisting of the first SMD tape as it continues to run can be, for example, thereby reliably prevented.

According to the exemplary method, an end section of the first SMD tape is then automatically threaded into an automatic belt connector by means of the robot arm controlled by the robot controller. The belt connector usually has a feed slot which is provided to briefly accommodate the first SMD component reel and/or later the second SMD component reel so that the given end section of the first SMD tape of the first SMD component reel or the start section of the second SMD tape of the second SMD component reel can be automatically grasped by the belt connector for the subsequent automatic connection of the end section of the first SMD tape to the start section of the second SMD tape.

In particular, the first SMD component reel is automatically separated from the first SMD tape even inside the belt connector.

The separated first SMD component reel is placed in an intermediate storage magazine by an automatic second movement of the robot arm controlled by the robot controller. This frees the gripper guided by the robot arm to grasp and handle the second SMD component reel, i.e. to be able to move it automatically.

According to the exemplary method, the second SMD component reel which carries a second SMD tape is then picked up from a pick-up magazine by means of the robot arm controlled by the robot controller. The second SMD component reel is generally a new SMD component reel, i.e. a SMD component reel that is fully populated with SMD components. The SMD component reel is filled in particular completely with the populated SMD tape. The pick-up magazine can therefore form a storage location at which fully filled SMD component reels are kept in stock.

According to the exemplary method, a start section of the second SMD tape is then automatically threaded into the automatic belt connector by means of the robot arm controlled by the robot controller. For this purpose, the belt connector has the aforementioned feed slot which is provided to briefly accommodate the second SMD component reel so that the given start section of the second SMD tape of the second SMD component reel can be automatically grasped by the belt connector for the subsequent automatic connection of the end section of the first SMD tape to the start section of the second SMD tape.

Finally, the exemplary method automatically inserts the second SMD component reel into the exchange magazine of the SMD assembly machine after the start section of the second SMD tape of the second SMD component reel has been automatically connected to the end section of the first SMD tape in the belt connector.

Since at this time the start section of the second SMD tape of the second SMD component reel is already connected to the end section of the first SMD tape, a tensile force is already being applied to the second SMD tape during the automatic insertion of the second SMD component reel into the exchange magazine of the SMD assembly machine. As when removing the first SMD component reel from the exchange magazine, also when inserting the second SMD component reel into the exchange magazine, the robot arm controlled by the robot controller is controlled in a force/torque-controlled movement control mode.

Preferably, the robot controller can therefore be designed and configured to control the robot arm in such a way that the robot arm, by means of its gripper which is moved by the robot arm, handles the gripped second SMD component reel in such a way that the second SMD component reel is inserted into the exchange magazine in a direction parallel to its main extension plane, i.e. is inserted into the exchange magazine in a direction perpendicular to the reel rotation axis.

While the second SMD component reel is being inserted into the exchange magazine of the SMD assembly machine by means of the robot arm controlled by the robot controller in a force/torque-controlled movement control mode of the robot arm, it can be provided in particular that the second SMD component reel to be inserted is only rotated about its reel rotation axis (Z-axis) during its movement and does not perform any other rotational movement, for example about the corresponding X-axis or Y-axis. A twisting of the second SMD tape that is already running out can, for example, be thereby reliably prevented.

In a first development of the method, the robot arm can be controlled by the robot controller in such a way that the first SMD component reel is guided on its way between the exchange magazine of the SMD assembly machine and the belt connector by the robot arm on a movement path that lies at least substantially in a plane that runs parallel to the feed direction of the first SMD tape of the first SMD component reel into the SMD assembly machine. This means that the first SMD component reel should at most be rotated around an axis of rotation that runs parallel to the reel rotation axis (Z-axis). Rotation of the first SMD component reel around a rotation axis (X-axis, Y-axis) that runs perpendicular to the reel rotation axis (Z-axis) should be prevented or not occur at all.

Alternatively or additionally, the robot arm can be controlled by the robot controller in such a way that the second SMD component reel is guided by the robot arm on its way between the belt connector and the exchange magazine of the SMD assembly machine on a movement path that lies at least substantially in a plane that runs parallel to the feed direction of the second SMD tape of the second SMD component reel into the SMD assembly machine. This means that the second SMD component reel should also at most be rotated around an axis of rotation that runs parallel to the reel rotation axis (Z-axis). Here too, rotation of the second SMD component reel around a rotation axis (X-axis, Y-axis) that runs perpendicular to the reel rotation axis (Z-axis) should be prevented or not occur at all.

In such a development of the method, the robot arm can be controlled by the robot controller such that the first SMD component reel is guided by the robot arm on its way between the exchange magazine of the SMD assembly machine and the belt connector along a movement path on which the first SMD component reel does not perform a rotation or only performs a rotation exclusively around its reel rotation axis, and/or the robot arm can be controlled by the robot controller such that the second SMD component reel is guided by the robot arm on its way between the belt connector and the exchange magazine of the SMD assembly machine along a movement path on which the second SMD component reel does not perform a rotation or only performs a rotation exclusively around its reel rotation axis.

The first SMD component reel can be rotatably mounted in a first cassette which has at least one first output gear that can be driven by a drive pinion of a gripper guided by the robot arm, wherein by driven rotation of the first output gear of the first cassette, the first SMD component reel is rotated for winding on or unwinding the first SMD tape within the first cassette in order to transport the first SMD tape synchronously with the automatic movement of the first SMD component reel on its movement path between the exchange magazine of the SMD assembly machine and the belt connector.

The tape drum of the first SMD component reel can therefore be rotatably mounted on at least one inner wall, in particular between two opposite inner walls of the cassette. The at least one inner wall can, for example, have an axle stub onto which the SMD component reel can be rotatably plugged. The SMD component reel can therefore be mounted on one side on a single inner wall or on both sides on two opposite inner walls. The given axle stub can have at least one locking projection on which the SMD component reel with its hub can be secured against axial detachment. One inner wall can be provided on a cover of the cassette. The cover can in particular be detachably fastened to a base body of the cassette. The lid can be pivotally mounted on the base body of the cassette, for example by means of a hinge, for opening and closing. The output gear can be firmly connected to the first SMD component roller. The housing of the cassette can have at least one opening through which a sprocket of the output gear is accessible from the outside. Through such an opening, a drive pinion can project into the cassette and mesh with the sprocket of the output gear. If the drive pinion is driven, the output gear can be rotated automatically, in particular rotating optionally clockwise or rotating counterclockwise. The rotating output wheel also moves the tape drum so that, depending on the direction of rotation, the SMD tape can optionally be actively unwound from the tape drum of the first SMD component reel or actively wound on.

The drive pinion can be driven by a motor, in particular an electric motor. The drive pinion and in particular also the motor can be arranged on a gripper which is designed to automatically grip the first SMD component reel. The gripper can be attached to a tool flange of the robot arm. Accordingly, the gripper can be moved by moving the robot arm. Once the gripper has gripped the first SMD component reel, the robot arm can be moved in space in the desired manner according to the method controlled by the robot controller. The gripper or the motor can be controlled by the robot controller so that not only can the robot controller carry out the movement of the first SMD component reel but also the SMD tape can be automatically conveyed out of the cassette or drawn in as required and coordinated with the movements of the first SMD component reel in space.

In the same way, the second SMD component reel can also be rotatably mounted in a second cassette which has at least one second output gear that can be driven by a drive pinion of a gripper guided by the robot arm, wherein by driven rotation of the second output gear of the second cassette, the second SMD component reel is rotated within the second cassette for winding on or unwinding the second SMD tape in order to transport the second SMD tape synchronously with the automatic movement of the second SMD component reel on its movement path between the belt connector and the exchange magazine of the SMD assembly machine.

The tape drum of the second SMD component reel can also be rotatably mounted on at least one inner wall, in particular between two opposite inner walls of the cassette. The at least one inner wall can, for example, have an axle stub on which the SMD component reel can be rotatably attached. The SMD component reel can therefore be mounted on one side on a single inner wall or on both sides on two opposite inner walls. The given axle stub can have at least one locking projection on which the SMD component reel with its hub can be secured against axial detachment. One inner wall can be provided on a cover of the cassette. The cover can in particular be detachably fastened to a base body of the cassette. The lid can be pivotally mounted on the base body of the cassette, for example by means of a hinge, for opening and closing. The output gear can be firmly connected to the second SMD component roller. The housing of the cassette can have at least one opening through which a sprocket of the output gear is accessible from the outside. Through such an opening, a drive pinion can project into the cassette and mesh with the sprocket of the output gear. If the drive pinion is driven, the output gear can be rotated automatically, in particular rotating optionally clockwise or rotating counterclockwise. The rotating output wheel moves the tape drum so that, depending on the direction of rotation, the SMD tape can either be actively unwound from the tape drum of the second SMD component reel or be actively wound on.

The drive pinion can be driven by a motor, in particular an electric motor. The drive pinion and in particular also the motor can be arranged on a gripper which is designed to automatically grip the second SMD component reel. The gripper can be attached to a tool flange of the robot arm. Accordingly, the gripper is to be moved by moving the robot arm, and once the gripper has gripped the second SMD component reel, the robot arm is to be moved in space in the desired manner according to the method controlled by the robot controller. The gripper or the motor can be controlled by the robot controller, so that not only can the robot controller carry out the movement of the second SMD component reel but also the SMD tape can be automatically fed out of the cassette or drawn in as required and coordinated with the movements of the second SMD component reel in the room.

In a further development of the method, the automatic threading of the end section of the first SMD tape into the automatic belt connector can be carried out by means of the robot arm controlled by the robot controller in a force/torque-controlled movement control mode of the robot arm, and/or the automatic insertion of the start section of the second SMD tape into the automatic belt connector can be carried out by means of the robot arm controlled by the robot controller in a force/torque-controlled movement control mode of the robot arm.

The robot arm can, controlled by the robot controller, handle a standardized cassette of identical design and size, wherein the standardized cassette is designed and configured to optionally store an SMD component reel of a specific size, a specific reel width, a specific reel diameter and/or a specific component type, or to store an SMD component reel of a different size, a different reel width, a different reel diameter and/or a different component type.

The standardized cassette can have a data carrier which, in addition to its function as a data carrier, also forms a marking by means of which the robot arm can automatically align itself with respect to the cassette to be gripped in order to be able to approach and grip the cassette detected by the marking with precise positioning by means of its gripper guided by the robot arm.

For this purpose, the robot arm and/or the gripper can have a detection device which is designed to detect the marking when the robot arm or the gripper is in the vicinity of the marking. The marking can, for example, be an optical marking and the detection device can be a camera. The optical marking can have optical, particularly digital, marks such as lines or dots. For example, the optical marking can be formed by a bar code or a QR code. The marking can encode data, for example about the type and/or number of SMD components that are present on the SMD component reel. Data about the dimensions, i.e. the size and/or width of the cassette, can also be encoded in the marking. Markers can also be in the marking that are arranged in a predefined position and location relative to a reference point on the cassette. The reference point on the cassette can, for example, be a point at the exit opening from which the SMD tape exits the cassette. Another reference point can be a location in the area of a gripping section of the cassette for being grasped by the gripper. The gripping section can, for example, be a specific locking projection or a specific locking niche in the cassette.

The robot arm can in particular be arranged on an autonomous vehicle, and the autonomous vehicle can be designed to automatically move the robot arm between a supply station, at which SMD component reels populated with SMD components are provided for transport to an SMD assembly machine, and the exchange magazine of the SMD assembly machine, into which at least one provided SMD component reel is to be loaded.

The autonomous vehicle can, for example, be designed as an omnidirectional vehicle. The omnidirectional vehicle can accordingly have one or more automatically drivable omnidirectional wheels. An autonomous vehicle is understood to be a vehicle that can move independently without manual control by a human driver being necessary. The autonomous vehicle can form a so-called driving platform on which the robot arm, the belt connector and/or an intermediate storage magazine are arranged. By means of the autonomous vehicle, the robot arm, the belt connector and/or the intermediate storage magazine can be automatically transported from one operating location to another operating location. Accordingly, the robot arm, the belt connector and/or the intermediate storage magazine can be automatically moved to a specific SMD assembly machine in order to carry out the method according to the invention there.

A belt connector automatically rotatable by 180 degrees can be arranged on the autonomous vehicle, and the belt connector can be turned from its current orientation into an orientation rotated by 180 degrees when the robot arm arranged on the autonomous vehicle with the first SMD component reel and/or the second SMD component reel is to carry out the automatic removal of the first SMD component reel and/or the automatic insertion of the second SMD component reel at an SMD assembly machine on a side of the autonomous vehicle opposite the previous working side.

The autonomous vehicle can have an automatically drivable turntable on which the belt connector is arranged. The turntable can be automatically driven by a drive motor, in particular an electric drive motor, in particular controlled by the robot controller of the robot arm. For example, if a plurality of SMD assembly machines are arranged in a factory hall in at least two parallel production lines, a space lying between the two production lines can serve as a driving corridor for the autonomous vehicle. This means that the robot arm carried by the autonomous vehicle can optionally operate the SMD assembly machines on the production lines lying on the left-hand side, or the SMD assembly machines on the production lines lying on the right-hand side. If the belt connector has a feeding device that can only be loaded in one direction, it is useful if the entire belt connector can be rotated by 180 degrees on the autonomous vehicle so that the feeding device can align its orientation optionally with the SMD assembly machines of the production lines lying on the left-hand side or with the SMD assembly machines of the production lines lying on the right-hand side. As a result, the autonomous vehicle does not have to be turned around in order to serve the other production lines.

The intermediate storage magazine can be provided on the autonomous vehicle. The intermediate storage magazine can have one or more slots for one or more cassettes. Because the autonomous vehicle has the intermediate storage magazine, the robot arm can place a cassette previously grasped by the gripper directly on the autonomous vehicle without having to drive to a special storage location. This allows the robot arm to switch between different cassettes with its gripper.

An example of a process can look like this:

The mobile robot or mobile system (autonomous vehicle with robot arm and belt connector) receives the order to pick up and distribute the cassettes via the central controller of the SMT lines (group of SMD assembly machines). Since the mobile robot is to work in the aisle between two SMT lines, the material requirements of two lines must be merged, prioritized and transmitted to the mobile system.

The cassette is prepared in advance according to production requirements via a material management system and made available at the collection point, a drop point.

The central computer of the SMT production lines transmits the material requirements of reels or cassettes to the mobile robot via an interface. This requirement corresponds to the contents of the cassette at the drop point. The demand for reels for the given SMT lines in a specific side aisle is combined by the central computer, and the prioritization is determined.

After successful order transfer from the SMT central computer, the mobile robot moves to the drop point and removes the cassette with full reels.

On the basis of the order list, the mobile robot travels to the first position of the reel or cassette to be changed. After a rough and fine positioning by the system on the SMT, for example using QR codes, the robot receives the order to start with changing.

The robot travels to the old cassette and uses a camera to check the QR code on the cassette. The correctness is checked here. The robot removes the cassette.

After the cassette has been removed from the exchange magazine, the cassette information is transferred to the splicer (belt connector). The splicer adjusts itself on the basis of the cassette data. The cassette is pulled over the splicer by the robot while the component tape is being placed into the opening of the splicer. The cassette is laterally positioned on the splicer.

The splicer takes the old tape and conveys it out of the cassette until the last full component pocket is detected. At this point, the tape is cut. The robot gripper reels the remaining tape with the empty component pockets back in, or the splicer pushes the remaining tape back into the cassette.

The old cassette is placed at an intermediate position on the mobile robot. The new cassette required according to the order list is rechecked by the camera on the gripper and removed. The cassette is then positioned on the splicer.

The new tape is drawn in by the splicer. The prepared tape of the new reel is spliced with the old tape (proper connection of component carrier tape and cover film in the belt connector).

After the tapes have been connected to each other, the cassette is transported by the robot towards the exchange magazine. In so doing, the tape is wound on by the gripper while taking into account the permissible forces, and the cassette is inserted into the exchange magazine.

The robot takes the old cassette from the intermediate storage magazine and places it in the vacated position of the cassette box.

After all cassettes have been exchanged, the mobile robot returns to the drop point and hands over the cassette box with the old cassettes.

The mobile robot is able to move automatically in an aisle between two SMT production lines. Here, the system serves the side that is located in this one aisle.

With the development of a robot-based handling system for reel exchange, it is possible to completely automate the work steps previously carried out manually, doing so without significantly changing the existing infrastructure. This represents a not inconsiderable cost advantage for the electronics industry.

Specific embodiments of the invention are explained in more detail in the following description with reference to the accompanying drawings. Specific features of these embodiments, possibly considered individually or in further combinations, can represent general features of the invention, regardless of the specific context in which they are mentioned.

### BRIEF DESCRIPTION OF THE DRAWINGS

The accompanying drawings, which are incorporated in and constitute a part of this specification, illustrate exemplary embodiments of the invention and, together with a general description of the invention given above, and the detailed description given below, serve to explain the principles of the invention.

FIG. 1 is a schematic representation of three exemplary SMD assembly machines, each with an exchange magazine in which a plurality of SMD component reels have been inserted,

FIG. 2 is a flow chart of the steps in the basic method according to the present disclosure,

FIG. 3 is a perspective representation of an exemplary autonomous vehicle with a robot arm, a belt connector and an intermediate storage magazine in a view from the left-hand side of the vehicle,

FIG. 4 is a perspective representation of the exemplary autonomous vehicle with the robot arm, the belt connector and the intermediate storage magazine in a view from the right-hand side of the vehicle,

FIG. 5 is a perspective representation of the exemplary autonomous vehicle with the robot arm, the belt connector and the intermediate storage magazine in a view from behind,

FIG. 6 is a perspective representation of the exemplary autonomous vehicle with the robot arm, the belt connector and the intermediate storage magazine in a view from the front,

FIG. 7 is an enlarged partial view of the autonomous vehicle in the region of a turntable of the autonomous vehicle, on which the belt connector is pivotably mounted by 180 degrees,

FIG. 8 is a schematic representation of a cassette in which an exemplary SMD component reel is stored,

FIG. 9 is a schematic representation of the cassette in which the exemplary SMD component reel is stored with a coupled gripper that is attached to the flange of the robot arm,

FIG. 10 is a perspective partial representation of the cassette in the region of the exit mouth of the SMD tape, in a closed position of a locking means,

FIG. 11 is a perspective partial representation of the cassette in the region of the exit mouth of the SMD tape, in an open position of the locking means,

FIG. 12 is a schematic representation in a side view of an exemplary

gripper in isolation, and

FIG. 13 is a perspective representation of the exemplary gripper according to FIG. 12 in isolation.

### DETAILED DESCRIPTION

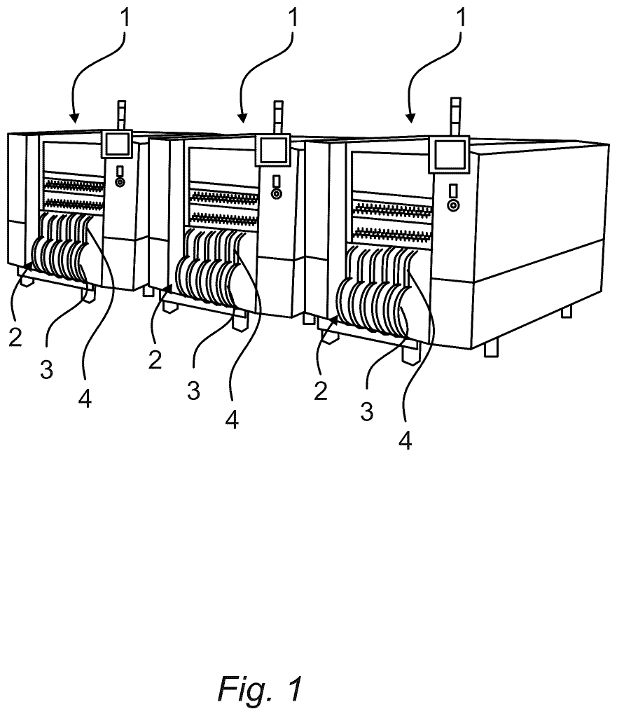

In FIG. 1, three representative SMD assembly machines 1 are shown. Each SMD assembly machine 1 has an exchange magazine 2 in which a plurality of different SMD component reels 3 have been inserted. From each SMD component reel 3, an SMD tape 4 runs into the corresponding SMD assembly machine 1.

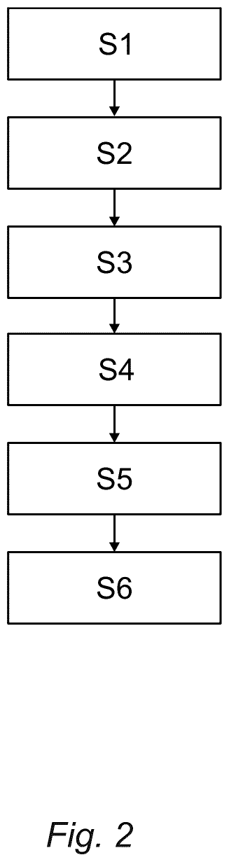

In FIG. 2, the basic method for automatically reloading SMD component reels 3 on SMD assembly machines 1 is shown schematically as a flow chart.

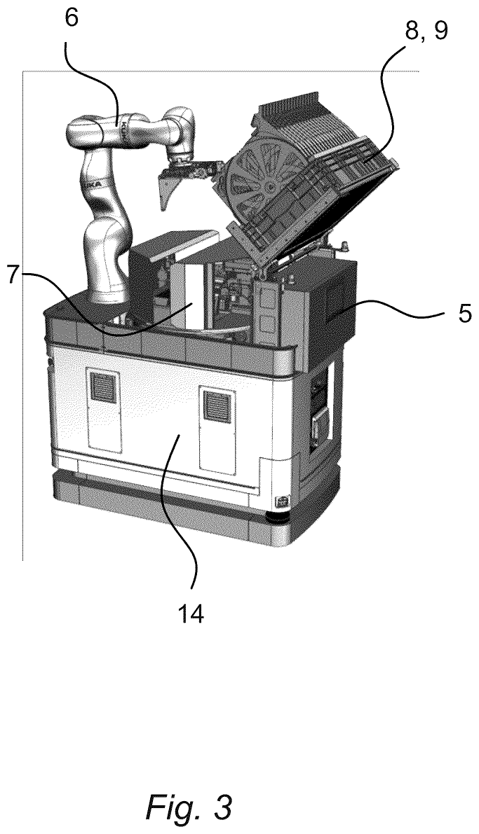

In a first method step S1, a first SMD component reel 3.1 is automatically removed, which carries a first SMD tape 4.1 that continues to run into the SMD assembly machine 1 in ongoing operation of an SMD assembly machine 1, while the first SMD component reel 3.1 is removed from an exchange magazine 2 of the SMD assembly machine 1 by means of a robot arm 6 (FIG. 3) controlled by a robot controller 5 in a force/torque-controlled movement control mode of the robot arm 6.

In a second method step S2, an end section of the first SMD tape 4.1 is automatically threaded into an automatic belt connector 7 by means of the robot arm 6 controlled by the robot controller 5, and the first SMD component reel 3.1 is automatically separated from the first SMD tape 4.1.

In a third method step S3, the first SMD component reel 3.1 is placed in an intermediate storage magazine 8.

In a fourth method step S4, a second SMD component reel 3.2 which carries a second SMD tape 4.2 is picked up from a pick-up magazine 9 by means of the robot arm 6 controlled by the robot controller 5.

In a fifth method step S5, a start section of the second SMD tape 4.2 is automatically threaded into the automatic belt connector 7 by means of the robot arm 6 controlled by the robot controller 5.

In a sixth method step S6, the second SMD component reel 3.2 is automatically inserted into the exchange magazine 2 of the SMD assembly machine 1 after a start section of the second SMD tape 4.2 of the second SMD component reel 3.2 has been automatically connected to the end section of the first SMD tape 4.1 in the belt connector 7, while the second SMD tape 4.2 runs off the second SMD component reel 3.2 in ongoing operation of the SMD assembly machine 1, wherein the second SMD component reel 3.2 is inserted into the exchange magazine 2 of the SMD assembly machine 1 by means of the robot arm 6 controlled by the robot controller 5 in a force/torque-controlled movement control mode of the robot arm 6.

The robot arm 6 is controlled by the robot controller 5 such that the first SMD component reel 3.1 is guided on its way between the exchange magazine 2 of the SMD assembly machine 1 and the belt connector 7 by the robot arm 6 on a movement path that lies at least substantially in a plane that runs parallel to the feed direction of the first SMD tape 4.1 of the first SMD component reel 3.1 into the SMD assembly machine 1.

The robot arm 6 is also controlled by the robot controller 5 in such a way that the second SMD component reel 3.2 is guided by the robot arm 6 on its way between the belt connector 7 and the exchange magazine 2 of the SMD assembly machine 1 on a movement path that lies at least substantially in a plane that runs parallel to the feed direction of the second SMD tape 4.2 of the second SMD component reel 3.2 into the SMD assembly machine 1.

The robot arm 6 can be controlled by the robot controller 5 in such a way that the first SMD component reel 3.1 is guided on its way between the exchange magazine 2 of the SMD assembly machine 1 and the belt connector 7 by the robot arm 6 on a movement path on which the first SMD component reel 3.1 does not perform a rotation, or only performs a rotation exclusively about its reel rotation axis. The robot arm 6 can also be controlled by the robot controller 5 in such a way that the second SMD component reel 3.2 can be guided on its way between the belt connector 7 and the exchange magazine 2 of the SMD assembly machine 1 by the robot arm 6 on a movement path on which the second SMD component reel 3.2 does not perform a rotation, or only performs a rotation exclusively about its reel rotation axis.

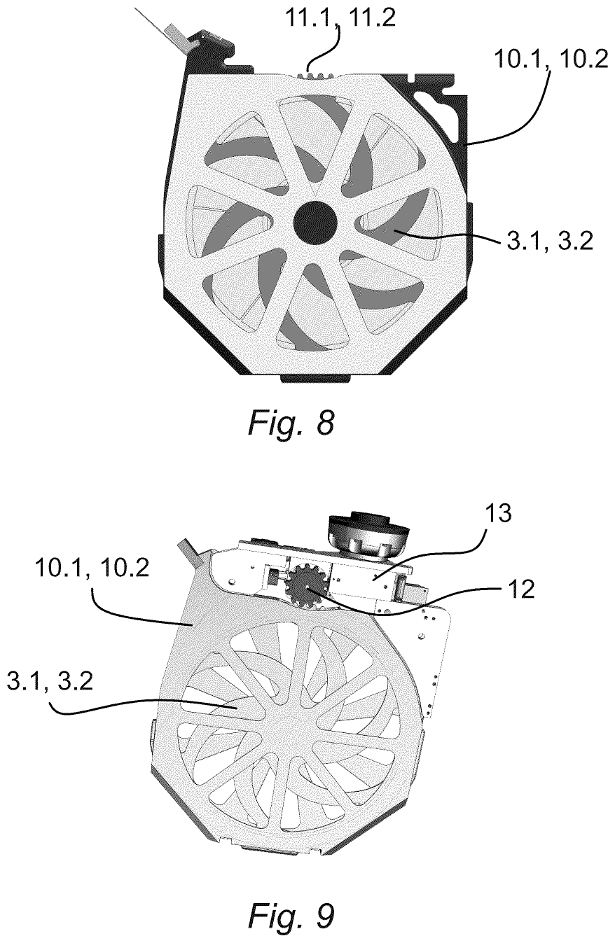

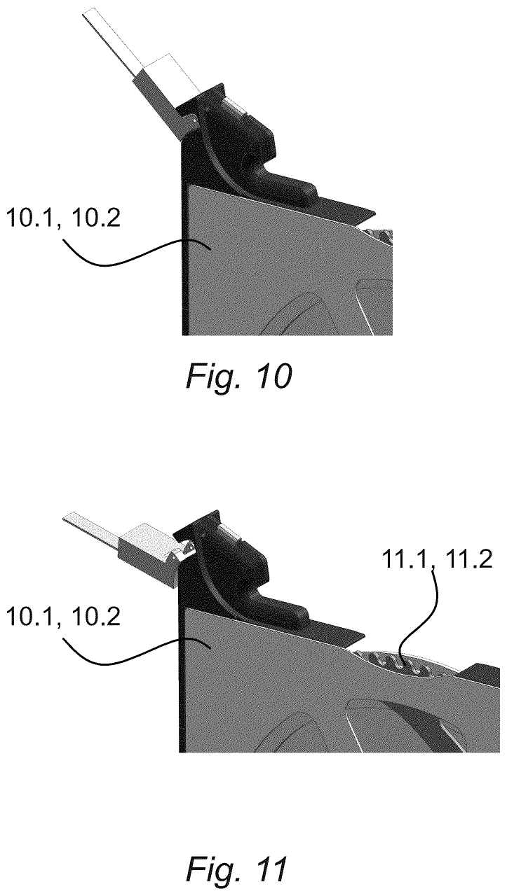

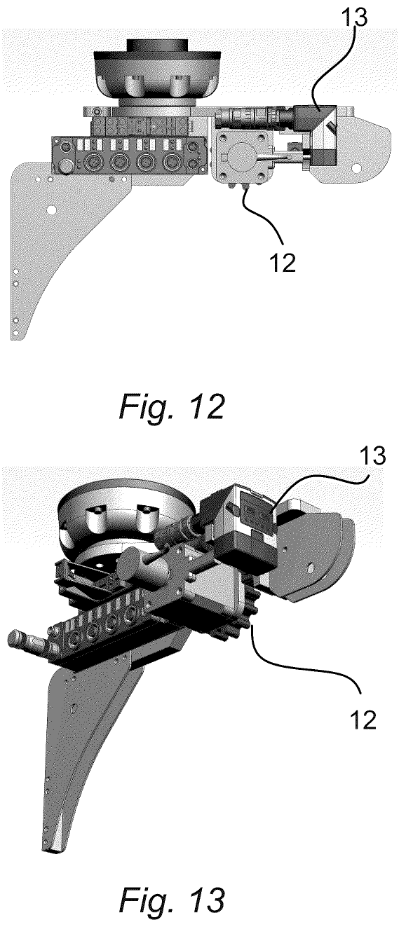

The first SMD component reel 3.1 can be rotatably mounted in a first cassette 10.1, as shown in FIG. 8 to FIG. 11, which has at least one first output gear 11.1 that can be driven by a drive pinion 12 (FIG. 9) of a gripper 13 (FIG. 12 and FIG. 13) guided by the robot arm 6, wherein by driven rotation of the first output gear 11.1 of the first cassette 10.1, the first SMD component reel 3.1 is rotated for winding on or unwinding the first SMD tape 4.1 within the first cassette 10.1 in order to transport the first SMD tape 4.1 synchronously with the automatic movement of the first SMD component reel 3.1 on its movement path between the exchange magazine 2 of the SMD assembly machine 1 and the belt connector 7.

In the same way, the second SMD component reel 3.2 can be rotatably mounted in a second cassette 10.2 which has at least one second output gear 11.2 that can be driven by the drive pinion 12 of the gripper 13 guided by the robot arm 6 (FIG. 12 and FIG. 13), wherein by driven rotation of the second output gear 11.2 of the second cassette 10.2, the second SMD component reel 3.2 is rotated within the second cassette 10.2 for winding on or unwinding the second SMD tape 4.2 in order to transport the second SMD tape 4.2 synchronously with the automatic movement of the second SMD component reel 3.2 on its movement path between the belt connector 7 and the exchange magazine 2 of the SMD assembly machine 1.

The automatic threading of the end section of the first SMD tape 4.1 into the automatic belt connector 7 is carried out by means of the robot arm 6 controlled by the robot controller 5 in a force/torque-controlled movement control mode of the robot arm 6. The automatic insertion of the start section of the second SMD tape 4.2 into the automatic belt connector 7 by means of the robot arm 6 controlled by the robot controller 5 is also carried out in a force/torque-controlled movement control mode of the robot arm 6.

The robot arm 6, controlled by the robot controller 5, handles a standardized cassette 10.1, 10.2 of identical design and size, wherein the standardized cassette 10.1, 10.2 is designed and configured to optionally store an SMD component reel 3.1, 3.2 of a specific size, a specific reel width, a specific reel diameter and/or a specific component type or to store an SMD component reel 3.1, 3.2 of a different size, a different reel width, a different reel diameter and/or a different component type.

The standardized cassette 10.1, 10.2 can have a data carrier which, in addition to its function as a carrier of data, also forms a marking by means of which the robot arm 6 can automatically align itself with respect to the cassette 10.1, 10.2 in order to be gripped in order to be able to approach and grip the cassette 10.1, 10.2 detected by the marking with precise positioning using its gripper 13 guided by the robot arm 6.

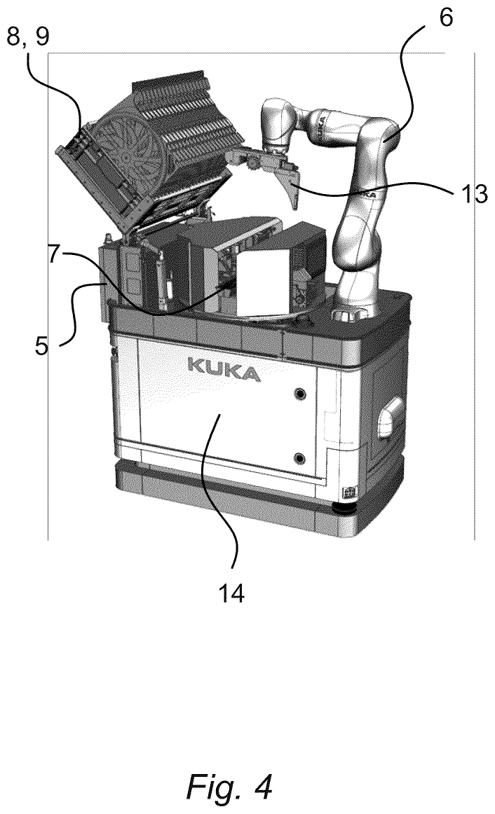

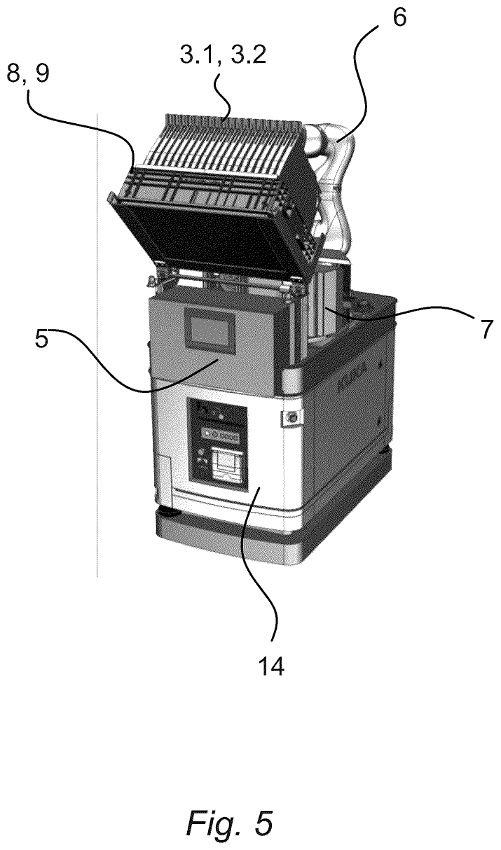

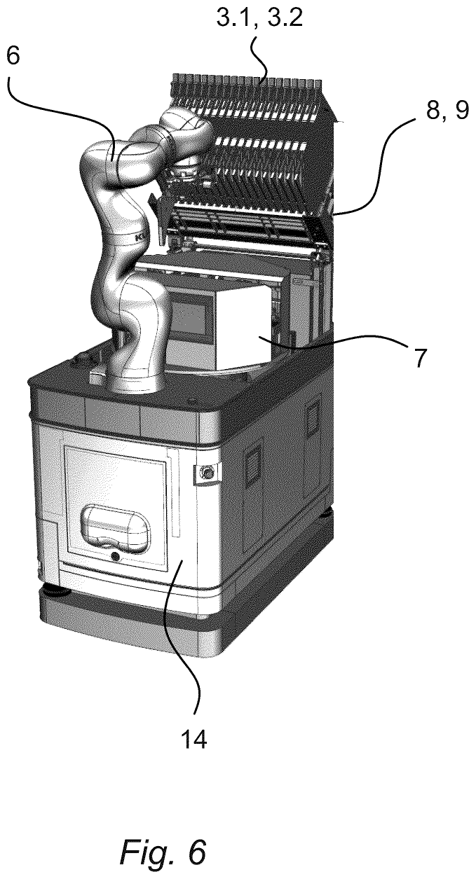

As shown in FIG. 3 to FIG. 7, in the case of the present exemplary embodiment, the robot arm 6 is arranged on an autonomous vehicle 14, and the autonomous vehicle 14 is designed to automatically move the robot arm 6 between a supply station at which SMD component reels 10.1, 10.2 populated with SMD components are provided for transport to an SMD assembly machine 1, and the exchange magazine 2 of the SMD assembly machine 1 into which at least one provided SMD component reel 10.1, 10.2 is to be loaded.

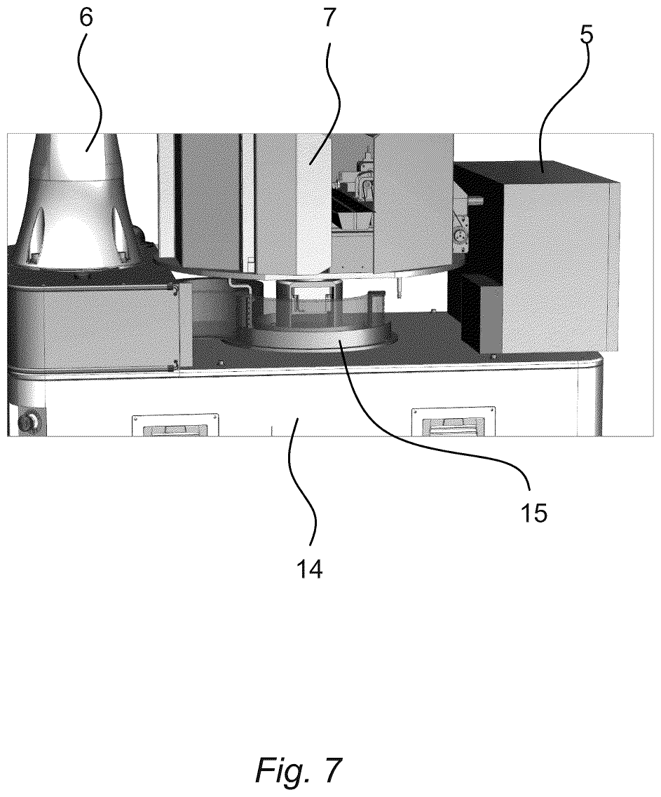

In the case of the present exemplary embodiment, a belt connector 7 automatically rotatable by 180 degrees by means of a turntable 15 (FIG. 7) is arranged on the autonomous vehicle 14, and the belt connector 7 can be turned from its current orientation into an orientation rotated by 180 degrees when the robot arm 6 arranged on the autonomous vehicle 14 with the first SMD component reel 10.1 and/or the second SMD component reel 10.2 carries out the automatic removal of the first SMD component reel 10.1 and/or the automatic insertion of the second SMD component reel 10.2 on an SMD assembly machine 1 on a side of the autonomous vehicle 14 opposite the previous working side. The intermediate storage magazine 8 or the pick-up magazine 9 is also provided on the autonomous vehicle 14.

While the present invention has been illustrated by a description of various embodiments, and while these embodiments have been described in considerable detail, it is not intended to restrict or in any way limit the scope of the appended claims to such de-tail. The various features shown and described herein may be used alone or in any combination. Additional advantages and modifications will readily appear to those skilled in the art. The invention in its broader aspects is therefore not limited to the specific details, representative apparatus and method, and illustrative example shown and described. Accordingly, departures may be made from such details without departing from the spirit and scope of the general inventive concept.

1. A method for automatically reloading SMD component reels (3.1, 3.2) on SMD assembly machines (1), having the steps:
automatic removal of a first SMD component reel (3.1) which carries a first SMD tape (4.1) which continues to run into the SMD assembly machine (1) in ongoing operation of an SMD assembly machine (1), while the first SMD component reel (3.1) is removed from an exchange magazine (2) of the SMD assembly machine (1) by means of a robot arm (6) controlled by a robot controller (5) in a force/torque-controlled movement control mode of the robot arm (6),
automatic threading of an end section of the first SMD tape (4.1) into an automatic belt connector (7) by means of the robot arm (6) controlled by the robot controller (5) and automatic separation of the first SMD component reel (3.1) from the first SMD tape (4.1),
depositing the first SMD component reel (3.1) in an intermediate storage magazine (8),
picking up a second SMD component reel (3.2) that carries a second SMD tape (4.2) from a pick-up magazine (9) by means of the robot arm (6) controlled by the robot controller (5),
automatically threading a start section of the second SMD tape (4.2) into the automatic belt connector (7) by means of the robot arm (6) controlled by the robot controller (5), and
automatic insertion of the second SMD component reel (3.2) into the exchange magazine (2) of the SMD assembly machine (1) after a start section of the second SMD tape (4.2) of the second SMD component reel (3.2) has been automatically connected to the end section of the first SMD tape (4.1) in the belt connector (7), while the second SMD tape (4.2) runs off the second SMD component reel (3.2) in ongoing operation of the SMD assembly machine (1), wherein the second SMD component reel (3.2) is inserted into the exchange magazine (2) of the SMD assembly machine (1) by means of the robot arm (6) controlled by the robot controller (5) in a force/torque-controlled movement control mode of the robot arm (6).

2-10. (canceled)

11. The method according to claim 1, characterized in that the robot arm (6) is controlled by the robot controller (5) in such a way that the first SMD component reel (3.1) is guided on its way between the exchange magazine (2) of the SMD assembly machine (1) and the belt connector (7) by the robot arm (6) on a movement path that lies at least substantially in a plane that runs parallel to the feed direction of the first SMD tape (4.1) of the first SMD component reel (3.1) into the SMD assembly machine (1), and/or the robot arm (6) is controlled by the robot controller (5) in such a way that the second SMD component reel (3.2) is guided on its way between the belt connector (7) and the exchange magazine (2) of the SMD assembly machine (1) by the robot arm (6) on a movement path that lies at least substantially in a plane that runs parallel to the feed direction of the second SMD tape (4.2) of the second SMD component reel (3.2) into the SMD assembly machine (1).

12. The method according to claim 1, characterized in that the robot arm (6) is controlled by the robot controller (5) in such a way that the first SMD component reel (3.1) is guided by the robot arm (6) on its way between the exchange magazine (2) of the SMD assembly machine (1) and the belt connector (7) along a movement path on which the first SMD component reel (3.1) does not perform a rotation or only performs a rotation exclusively around its reel rotation axis, and/or the robot arm (6) is controlled by the robot controller (5) in such a way that the second SMD component reel (3.2) is guided by the robot arm (6) on its way between the belt connector (7) and the exchange magazine (2) of the SMD assembly machine (1) along a movement path on which the second SMD component reel (3.2) does not rotate or only rotates exclusively around its reel rotation axis.

13. The method according to claim 1, characterized in that the first SMD component reel (3.1) is rotatably mounted in a first cassette (10.1) which has at least one first output gear (11.1) which can be driven by a drive pinion (12) of a gripper (13) guided by the robot arm (6), wherein by driven rotation of the first output gear (11.1) of the first cassette (10.1), the first SMD component reel (3.1) is rotated within the first cassette (10.1) for winding on or unwinding the first SMD tape (4.1) in order to transport the first SMD tape (4.1) synchronously with the automatic movement of the first SMD component reel (3.1) on its movement path between the exchange magazine (2) of the SMD assembly machine (1) and the belt connector (7), and/or the second SMD component reel (3.2) is rotatably mounted in a second cassette (10.2) which has at least one second output gear (11.2) which can be driven by a drive pinion (12) of a gripper (13) guided by the robot arm (6), wherein by driven rotation of the second output gear of the second cassette (10.2), the second SMD component reel (3.2) is rotated within the second cassette (10.2) for winding on or unwinding the second SMD tape (4.2) in order to transport the second SMD tape (4.2) synchronously with the automatic movement of the second SMD component reel (3.2) on its movement path between the belt connector (7) and the exchange magazine (2) of the SMD assembly machine (1).

14. The method according to claim 1, characterized in that the automatic threading of the end section of the first SMD tape (4.1) into the automatic belt connector (7) is carried out by means of the robot arm (6) controlled by the robot controller (5) in a force/torque-controlled movement control mode of the robot arm (6), and/or the automatic insertion of the start section of the second SMD tape (4.2) into the automatic belt connector (7) is carried out by means of the robot arm (6) controlled by the robot controller (5) in a force/torque-controlled movement control mode of the robot arm (6).

15. The method according to claim 1, characterized in that, controlled by the robot controller (5), the robot arm (6) handles a standardized cassette (10.1, 10.2) of identical design and size, wherein the standardized cassette (10.1, 10.2) is designed and configured to optionally store an SMD component reel (3.1, 3.2) of a specific size, a specific reel width, a specific reel diameter and/or a specific component type or to store an SMD component reel (3.1, 3.2) of a different size, a different reel width, a different reel diameter and/or a different component type.

16. The method according to claim 15, characterized in that the standardized cassette (10.1, 10.2) has a data carrier which, in addition to its function as a carrier of data, also forms a marking by means of which the robot arm (6) can automatically align itself with respect to the cassette (10.1, 10.2) in order to be gripped in order to be able to approach and grip the cassette (10.1, 10.2) detected by the marking doing so with precise positioning using its gripper (13) guided by the robot arm (6).

17. The method according to claim 1, characterized in that the robot arm (6) is arranged on an autonomous vehicle (14), and the autonomous vehicle (14) is designed to move the robot arm (6) automatically between a supply station at which SMD component reels (3.1, 3.2) populated with SMD components are provided for transport to an SMD assembly machine (1), and the exchange magazine (2) of the SMD assembly machine (1) into which at least one provided SMD component reel (3.1, 3.2) is to be loaded.

18. The method according to claim 17, characterized in that a belt connector (7) automatically rotatable by 180 degrees is arranged on the autonomous vehicle (14), and the belt connector (7) is turned from its current orientation into an orientation rotated by 180 degrees when the robot arm (6) arranged on the autonomous vehicle (14) with the first SMD component reel (3.1) and/or the second SMD component reel (3.2) is to carry out the automatic removal of the first SMD component reel (3.1) and/or the automatic insertion of the second SMD component reel (3.2) on an SMD assembly machine (1) on a side of the autonomous vehicle (14) opposite the previous working side.

19. The method according to claim 17, characterized in that the intermediate storage magazine (8) is provided on the autonomous vehicle (14).
